(19) United States
(12) Patent Application Publication
(10) Pub. No.: US 2026/0133264 A1
(43) Pub. Date: May 14, 2026

(54) DISPLAY DEVICE

(71) Applicant: LG ELECTRONICS INC., Seoul (KR)

(72) Inventors: Sungwon PARK, Seoul (KR); Eunkwang JANG, Seoul (KR)

(73) Assignee: LG ELECTRONICS INC., Seoul (KR)

(21) Appl. No.: 19/362,746

(22) Filed: Oct. 20, 2025

(30) Foreign Application Priority Data
Nov. 8, 2024 (WO) PCT/KR2024/017659

(51) Int. Cl. G01R 33/07; G06F 1/16; G06F 1/18

(52) U.S. Cl. CPC G01R 33/072; G06F 1/1607; G06F 1/182

(57) ABSTRACT

A display device according to an embodiment of a present disclosure may comprise a head including a display, a sensor used to turn on or off a screen of the display, and a controller, wherein the controller may detect whether a stand supporting the head and the head are fastened, and deactivate a function of the sensor when it is detected that the stand is fastened with the head.

### CROSS-REFERENCE TO RELATED APPLICATIONS

Pursuant to 35 U.S.C. § 119, this application claims the benefit of earlier filing date and right of priority to International Application No. PCT/KR2024/017659, filed on November 8, 2024, the contents of which is hereby incorporated by reference herein in its entirety.

### BACKGROUND OF THE INVENTION

### 1. Field of the Invention

The present disclosure relates to a display device, and more specifically, to a stand-type display device.

### 2. Discussion of the Related Art

As the information society develops, the demand for display devices is increasing in various forms, and in response to this, various display devices such as LCD (Liquid Crystal Display Device), PDP (Plasma Display Panel), ELD (Electro luminescent display), VFD (Vacuum Fluorescent Display), and OLED (Organic Light Emitting Diode) have been researched and used.

The LCD panel has a TFT substrate and a color substrate that face each other with a liquid crystal layer in between, and may display images using light provided from a backlight unit.

OLED panels may display images by depositing an organic material layer that may emit light on its own on a substrate with transparent electrodes.

Recently, much research has been conducted on the structure of a display device in which a stand may be attached and detached from a head with a display function.

Users may attach the stand to the head and watch the video in a stand-type format, or detach the stand from the head and watch the video through the head.

When a user watches video through the head after detaching the stand, a folio cover that covers the head may be used. When the display panel provided on the head is covered by the folio cover, the screen of the head may be turned off by the magnetic field detected by the hall sensor.

However, conventional display devices did not have the function to detect whether the stand and the head were separated. In this case, when the user mounts the stand on the head and attaches a remote control wire equipped with a magnet to where the hall sensor of the head is located, there is a problem that the head's screen is turned off due to the magnetic field detected by the hall sensor.

Additionally, when using a display device in the form of a stand and when using only the head as a display device, sound quality settings and image quality settings may be different.

In this case, when the user uses the display device as a stand type and then separates the stand to use the display device as a head type, there is a problem in that the user must manually manipulate the setting values through the settings menu.

### SUMMARY OF THE INVENTION

The purpose of the present disclosure may be to prevent the hall sensor provided in the head from being activated unnecessarily.

The purpose of the present disclosure may be to disable the function of the hall sensor when the display device is used in the form of a stand that does not use a folio cover.

The purpose of the present disclosure may be to detect separation or mounting between the stand and the head and operate the display device with settings appropriate for the detected situation.

A display device according to an embodiment of a present disclosure may comprise a head including a display, a sensor used to turn on or off a screen of the display, and a controller, wherein the controller may detect whether a stand supporting the head and the head are fastened, and deactivate a function of the sensor when it is detected that the stand is fastened with the head.

A method of operating a display device according to an embodiment of a present disclosure, wherein the display device may comprise a head including a display, a sensor used to turn on or off a screen of the display, and a controller, the method may comprise detecting whether a stand supporting the head and the head are fastened; and deactivating a function of the sensor when it is detected that the stand is fastened with the head.

According to an embodiment of the present disclosure, when the stand and the head are fastened, the function of the hall sensor may be deactivated. Accordingly, the problem of the display screen turning off even when the user places the remote control device in a position adjacent to the magnet inside the head may be solved.

According to an embodiment of the present disclosure, the setting values of the display device may be automatically optimized depending on whether the stand is fastened to the head. Accordingly, the user no longer needs to manually operate the display device, and the ease of use of the display device may be greatly improved.

### BRIEF DESCRIPTION OF THE DRAWINGS

FIGS. 1A and 1B are diagrams illustrating the structure of a display device according to an embodiment of the present disclosure.

FIG. 2 is a block diagram showing the configuration of a display device according to an embodiment of the present disclosure.

FIG. 3A is a diagram illustrating a state in which the stand is fastened to the head according to an embodiment of the present disclosure.

FIG. 3B is a diagram illustrating a state in which the stand is separated from the head.

FIG. 4A is a diagram showing an open state in which the folio cover is not covering the head with the stand separated, and FIGS. 4B and 4C are diagrams showing the closed state in which the folio cover is covering the head with the stand separated.

FIG. 5 is a diagram explaining that the display screen is turned off due to a remote control device when the stand and head are fastened.

FIG. 6 is a flowchart explaining a method of operating a display device according to an embodiment of the present disclosure.

FIGS. 7 to 8B are diagrams illustrating a method for detecting whether a stand is fastened to a head according to an embodiment of the present disclosure.

FIG. 9 is a diagram explaining the arrangement structure of a magnet and a hall sensor provided in a head according to an embodiment of the present disclosure.

### DETAILED DESCRIPTION OF THE PREFERRED EMBODIMENTS

Hereinafter, embodiments related to the present invention will be described in more detail with reference to the drawing. The suffixes “module” and “part” for component used in the following description are given or used interchangeably only for the ease of preparing the specification, and do not have distinct meanings or roles in themselves.

The directional indications Up (U), Down (D), Left (Le), Right (Ri), Front (F), and Rear (R) shown in the drawings are provided for the convenience of explanation only and do not limit the technical ideas disclosed in this specification.

The display device according to an embodiment of the present invention is, for example, an intelligent display device that adds a computer support function to the broadcast reception function, and is faithful to the broadcast reception function while adding an Internet function, etc., such as a handwriting input device and a touch screen. Alternatively, it may be equipped with a more convenient interface such as a spatial remote control. In addition, by supporting wired or wireless Internet functions, it is possible to connect to the Internet and a computer and perform functions such as email, web browsing, banking, or gaming. A standardized general-purpose OS may be used for these various functions.

Accordingly, in the display device described in the present invention, for example, various applications may be freely added or deleted on a general-purpose OS kernel, so various user-friendly functions may be performed. More specifically, the display device may be, for example, a network TV, HBBTV, smart TV, LED TV, OLED TV, etc., and in some cases, may also be applied to a smartphone.

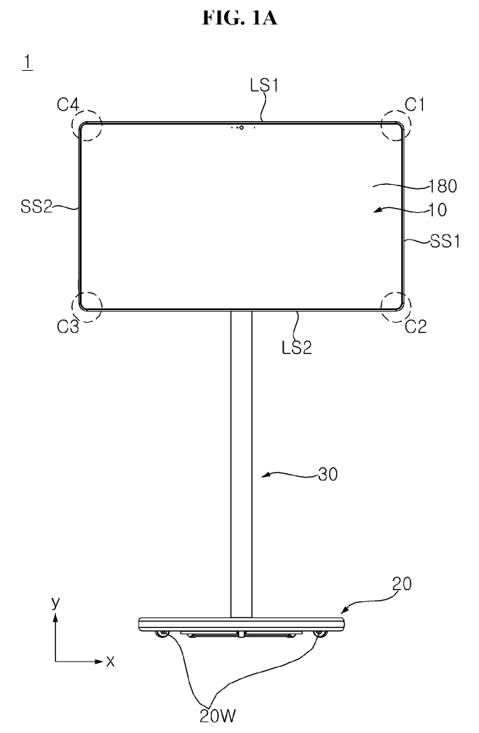

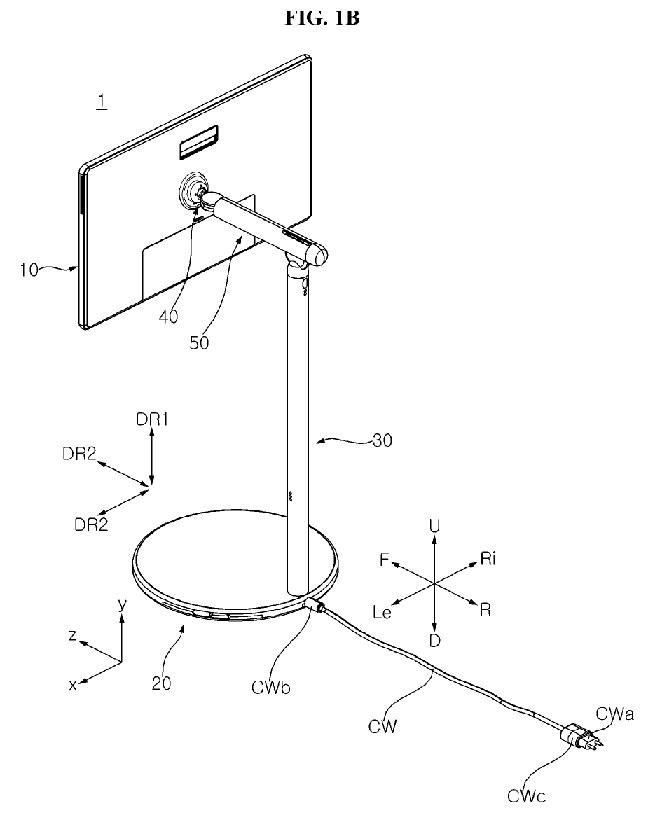

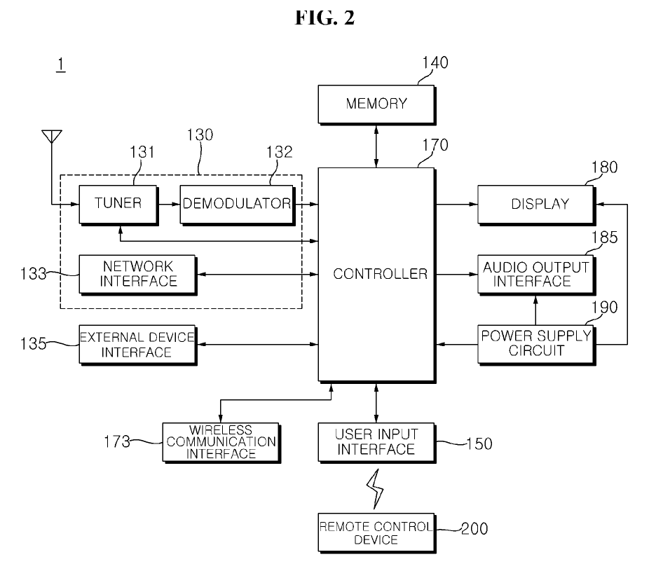

FIGS. 1A and 1B are diagrams illustrating the structure of a display device according to an embodiment of the present disclosure.

FIGS. 1A and 1B, the display device 1 may include a head 10. The head 10 may include a display panel that displays an image.

The head 10 may include a first long side (LS1), a second long side (LS2) opposing the first long side (LS1), a first short side (SS1) adjacent to the first long side (LS1), and the second long side (LS2) and a second short side (SS2) opposite to the first short side (SS1).

Meanwhile, for convenience of explanation, the length of the first and second long sides LS1 and LS2 is shown and described as being longer than the length of the first and second short sides SS1 and SS2. It may be possible that the length of the second long sides LS1 and LS2 is approximately the same as the length of the first and second short sides SS1 and SS2.

A direction parallel to the short sides (SS1, SS2) of the head 10 may be referred to as an up-down direction or a first direction DR1. The direction parallel to the long sides LS1 and LS2 of the head 10 may be referred to as a left and right direction or a second direction DR2. A direction perpendicular to the short sides (SS1, SS2) and long sides (LS1, LS2) of the head 10 may be referred to as a forward-backward direction or a third direction DR3.

The direction in which the head 10 displays an image may be referred to as a front (F, z), and the opposite direction may be referred to as a rear (R). The first short side (SS1) may be referred to as a left side (Le, x). The second short side (SS2) may be referred to as a right side (Ri). The first long side (LS1) may be referred to as a upper side (U, y). The second long side (LS2) may be referred to as a bottom side (D).

The first long side (LS1), the second long side (LS2), the first short side (SS1), and the second short side (SS2) may be referred to as edges of the head 10. The point where the first long side (LS1), the second long side (LS2), the first short side (SS1), and the second short side (SS2) meet each other may be called a corner. The point where the first short side (SS1) and the first long side (LS1) meet may be the first corner (C1). The point where the first short side (SS1) and the second long side (LS2) meet may be the second corner (C2). The point where the second short side (SS2) and the second long side (LS2) meet may be the third corner (C3). The point where the second short side (SS2) and the first long side (LS1) meet may be the fourth corner (C4).

The display device 1 may include stand 20, 30, 40, and 50 that support the head 10.

The stand 20, 30, 40, and 50 may include a base 20, a pole 30, a rotatable connector 40, and a support arm 50.

The stand 20, 30, 40, and 50 may be detachably coupled to the head 10.

The base 20 may be placed on the ground. The base 20 may be round or angular. A plurality of wheels 20W may be provided on a lower surface of the base 20.

The adapter (CWc) and plug (CWa) connected to the power cable (CW) may be connected to an outlet (concentric plug) that supplies external power.

A jack (CWb) of the power cable (CW) may be connected to the base 20.

The adapter (CWc) may convert external AC power to DC power, and supply the converted DC power to the jack (CWb).

A battery (not shown) may be built into the base 20, pole 30, support arm 50, and/or head 10, and may be charged by power supplied through the power cable (CW). The display device 1 may receive power from the battery and may be operated while disconnected from the power cable (CW).

The pole 30 may extend vertically from the base 20. A lower end of the pole 30 may be coupled to the pole 30 adjacent to a circumference of the base 20.

The support arm 50 may extend in a direction crossing the pole 30 and may be coupled to a top of the pole 30. The rotatable connector 40 may be located between the head 10 and the support arm 50 and may be coupled to the head 10 and the support arm 50.

The head 10 may be supported by stand 20, 30, 40, and 50 and may be spaced upward from the ground.

The rotatable connector 40 may rotate the head 10 up and down or left and right. When an external force is applied to the rotatable connector 40, the head 10 may be rotated in one or more of the up/down/left/right directions.

The rotatable connector 40 and the head 10 may have a detachable structure.

FIG. 2 is a block diagram showing a configuration of a display device according to an embodiment of the present disclosure.

Referring to FIG. 2, the display device 1 may include a broadcast receiver 130, an external device interface 135, a memory 140, a user input interface 150, a controller 170, a wireless communication interface 173, a display 180, a speaker 185, and a power supply circuit 190.

The broadcast receiver 130, the external device interface 135, the memory 140, the user input interface 150, the controller 170, the wireless communication interface 173, the display 180, the speaker 185, and the power supply circuit 190 may each be provided in the head 10. However, they are not limited to this arrangement, and some elements may also be provided in the stand 20, 30, 40, 50.

The broadcast receiver 130 may include a tuner 131, a demodulator 132, and a network interface 133.

The tuner 131 may select a specific broadcast channel according to a channel selection command. The tuner 131 may receive a broadcast signal for the selected specific broadcast channel.

The demodulator 132 may separate the received broadcast signal into an image signal, an audio signal, and a data signal related to a broadcast program, and restore the separated image signal, audio signal, and data signal to a format capable of being output.

The external device interface 135 may receive an application or a list of applications in an external device adjacent thereto, and transmit the same to the controller 170 or the memory 140.

The external device interface 135 may provide a connection path between the display device 1 and an external device. The external device interface 135 may receive one or more of images and audio output from an external device connected to the display device 1 in a wired or wireless manner, and transmit the same to the controller 170.

The external device interface 135 may include a plurality of external input terminals. The plurality of external input terminals may include an RGB terminal, one or more High Definition Multimedia Interface (HDMI) terminals, and a component terminal.

The image signal of the external device input through the external device interface unit 135 may be output through the display 180. The audio signal of the external device input through the external device interface 135 may be output through the speaker 185.

The external device connectable to the external device interface 135 may be any one of a set-top box, a Blu-ray player, a DVD player, a game machine, a sound bar, a smartphone, a PC, a USB memory, and a home theater, but this is only an example.

The external device interface 135 may be provided in one or more of the head 10 or the stand 20, 30, 40, 50.

The network interface 133 may provide an interface for connecting the display device 1 to a wired/wireless network including an Internet network.

The network interface 133 may transmit or receive data to or from other users or other electronic devices through a connected network or another network linked to the connected network.

In addition, a part of content data stored in the display device 1 may be transmitted to a selected user among a selected user or a selected electronic device among other users or other electronic devices registered in advance in the display device 1.

The network interface 133 may access a predetermined web page through the connected network or the other network linked to the connected network. That is, it is possible to access a predetermined web page through a network, and transmit or receive data to or from a corresponding server.

The network interface 133 may receive content or data provided by a content provider or a network operator. That is, the network interface 133 may receive content such as movies, advertisements, games, VOD, and broadcast signals and information related thereto provided from a content provider or a network provider through a network.

The network interface 133 may receive update information and update files of firmware provided by the network operator, and may transmit data to an Internet or content provider or a network operator.

The network interface 133 may select and receive a desired application from among applications that are open to the public through a network.

The memory 140 may store programs for signal processing and control of the controller 170, and may store images, audio, or data signals, which have been subjected to signal-processed.

The memory 140 may perform a function for temporarily storing images, audio, or data signals input from an external device interface 135 or the network interface 133, and store information on a predetermined image through a channel storage function.

The memory 140 may store an application or a list of applications input from the external device interface 135 or the network interface 133.

The display device 1 may play back a content file (a moving image file, a still image file, a music file, a document file, an application file, or the like) stored in the memory 140 and provide the same to the user.

The user input interface 150 may transmit a signal input by the user to the controller 170 or a signal from the controller 170 to the user. For example, the user input interface 150 may receive and process a control signal such as power on/off, channel selection, screen settings, and the like from the remote control device 200 in accordance with various communication methods, such as a Bluetooth communication method, a WB (Ultra Wideband) communication method, a ZigBee communication method, an RF (Radio Frequency) communication method, or an infrared (IR) communication method or may perform processing to transmit the control signal from the controller 170 to the remote control device 200.

In addition, the user input interface 150 may transmit a control signal input from a local key (not shown) such as a power key, a channel key, a volume key, and a setting value to the controller 170.

The image signal image-processed by the controller 170 may be input to the display 180 and displayed as an image corresponding to a corresponding image signal. Also, the image signal image-processed by the controller 170 may be input to an external output device through the external device interface 135.

The audio signal processed by the controller 170 may be output to the speaker 185. Also, the audio signal processed by the controller 170 may be input to the external output device through the external device interface 135.

In addition, the controller 170 may control the overall operation of the display device 1.

In addition, the controller 170 may control the display device 1 by a user command input through the user input interface 150 or an internal program and connect to a network to download an application a list of applications or applications desired by the user to the display device 1.

The controller 170 may allow the channel information or the like selected by the user to be output through the display 180 or the speaker 185 along with the processed image or audio signal.

In addition, the controller 170 may output an image signal or an audio signal through the display 180 or the speaker 185, according to a command for playing back an image of an external device through the user input interface 150, the image signal or the audio signal being input from an external device, for example, a camera or a camcorder, through the external device interface 135.

Meanwhile, the controller 170 may allow the display 180 to display an image, for example, allow a broadcast image which is input through the tuner 131 or an external input image which is input through the external device interface 135, an image which is input through the network interface unit or an image which is stored in the memory 140 to be displayed on the display 180. In this case, an image being displayed on the display 180 may be a still image or a moving image, and may be a 2D image or a 3D image.

In addition, the controller 170 may allow content stored in the display device 1, received broadcast content, or external input content input from the outside to be played back, and the content may have various forms such as a broadcast image, an external input image, an audio file, still images, accessed web screens, and document files.

The wireless communication interface 173 may communicate with an external device through wired or wireless communication. The wireless communication interface 173 may perform short range communication with an external device. To this end, the wireless communication interface 173 may support short range communication using at least one of Bluetooth™, Radio Frequency Identification (RFID), Infrared Data Association (IrDA), Ultra Wideband (UWB), ZigBee, Near Field Communication (NFC), Wi-Fi (Wireless-Fidelity), Wi-Fi(Wireless-Fidelity), Wi-Fi Direct, and Wireless USB (Wireless Universal Serial Bus) technologies.

The wireless communication interface 173 may support wireless communication between the display device 1 and a wireless communication system, between the display device 1 and another display device 1, or between the display device 1 and a network in which the display device 1 (or an external server) is located through wireless area networks. The wireless area networks may be wireless personal area networks.

The wireless communication interface 173 may detect (or recognize) a wearable device capable of communication around the display device 1.

When the detected wearable device is an authenticated device to communicate with the display device 1 according to the present disclosure, the controller 170 may transmit at least a portion of data processed by the display device 1 to the wearable device through the wireless communication interface 173. Therefore, a user of the wearable device may use data processed by the display device 1 through the wearable device.

The display 180 may convert image signals, data signals, and OSD signals processed by the controller 170, or image signals or data signals received from the external device interface 135 into R, G, and B signals, and generate drive signals.

Meanwhile, since the display device 1 shown in FIG. 1 is only an embodiment of the present disclosure, some of the illustrated components may be integrated, added, or omitted depending on the specification of the display device 1 that is actually implemented.

That is, two or more components may be combined into one component, or one component may be divided into two or more components as necessary. In addition, a function performed in each block is for describing an embodiment of the present disclosure, and its specific operation or device does not limit the scope of the present disclosure.

According to another embodiment of the present disclosure, unlike the display device 1 shown in FIG. 1, the display device 1 may receive an image through the network interface 133 or the external device interface 135 without a tuner 131 and a demodulator 132 and play back the same.

For example, the display device 1 may be divided into an image processing device, such as a set-top box, for receiving broadcast signals or content according to various network services, and a content playback device that plays back content input from the image processing device.

In this case, an operation method of the display device according to an embodiment of the present disclosure will be described below may be implemented by not only the display device 1 as described with reference to FIG. 1 and but also one of an image processing device such as the separated set-top box and a content playback device including the display 180 the speaker 185.

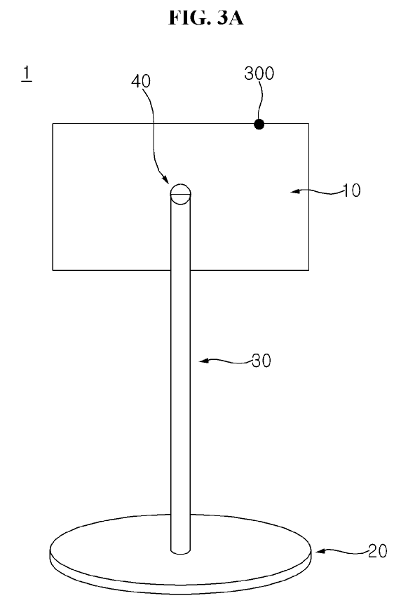

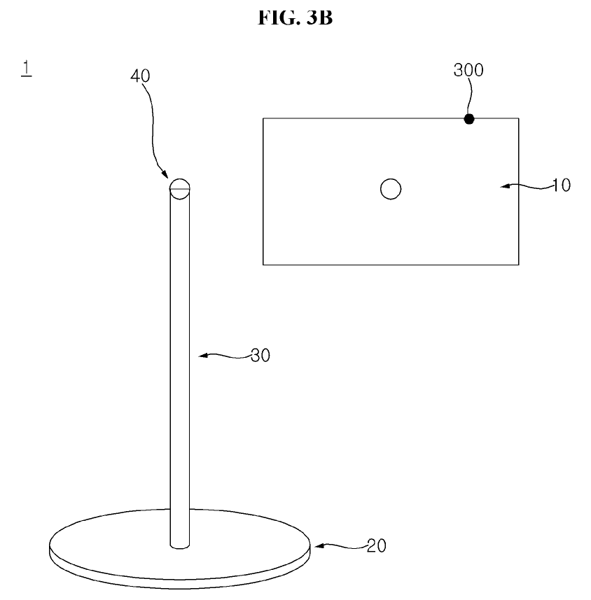

FIG. 3A is a diagram illustrating a state in which the stand is fastened to the head according to an embodiment of the present disclosure, and FIG. 3B is a diagram illustrating a state in which the stand is separated from the head.

FIGS. 3A and 3B show a rear view of the display device 1.

Referring to FIG. 3A, the stand 20, 30, 40, and 50 is shown in a fastened state to the head 10. The display device 1 may include a head 10 and stand 20, 30, 40, and 50 in a fastened state.

A user may use the display device 1 while moving the display device 1 including the head 10 and the stand 20, 30, 40, and 50.

Referring to FIG. 3B, the stand 20, 30, 40, and 50 is shown in a separated state from the head 10. The display device 1 may include only the head 10 in a separated state.

The user may hang the head 10 on the wall and use it in a fixed position.

A hall sensor 300 may be provided at the top of the head 10. The hall sensor 300 may be a sensor that detects a magnetic field and converts the detected magnetic field into an electrical signal. The hall sensor 300 may be a sensor used to detect whether the head 10 is covered with a cover. The hall sensor 300 may be a sensor used to turn on or off the screen of the display 180 provided on the head 10.

A cover (not shown) covers both sides of the head 10 and may be used to protect the head 10. The cover may be a folio cover equipped with a magnet.

When the head 10 is covered by the folio cover, the screen of the display 180 may be turned off. The head 10 may further include a magnet (not shown) disposed near the hall sensor 300. The hall sensor 300 may detect the magnetic field generated between the magnet provided on the folio cover and the magnet provided on the head 10. The head 10 may determine whether the head 10 is covered by the folio cover through the magnetic field detected through the hall sensor 300.

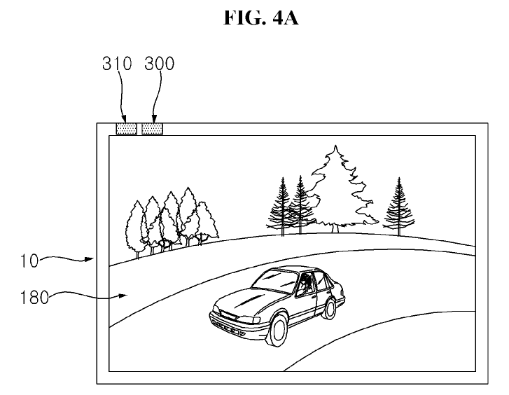

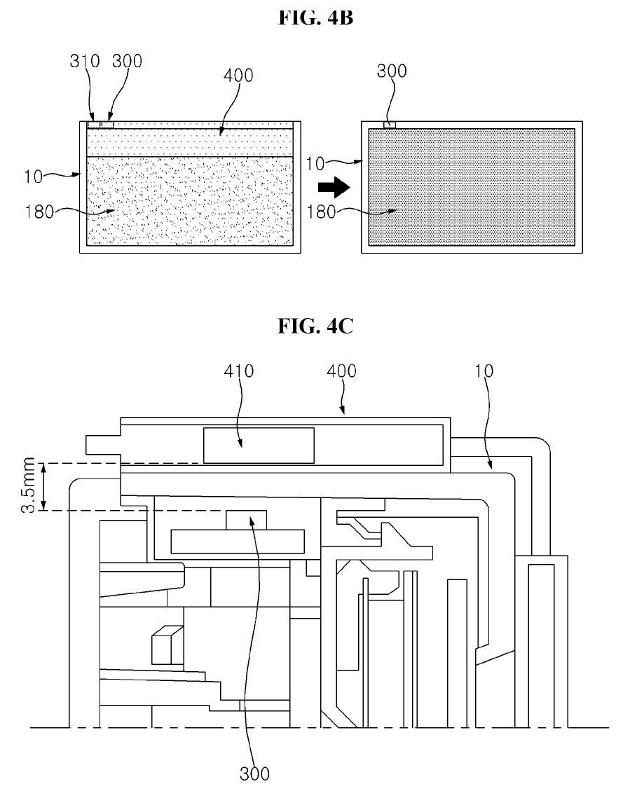

FIG. 4A is a diagram showing an open state in which the folio cover is not covering the head with the stand separated, and FIGS. 4B and 4C are diagrams showing the closed state in which the folio cover is covering the head with the stand separated.

FIGS. 4A and 4B, it is assumed that the stand 20, 30, 40, and 50 is separated from the head 10.

Referring to FIG. 4A, the head 10 that is not fastened to the stand 20, 30, 40, or 50 may display an image through the display 180 in an open state. The head 10 may determine whether the folio cover 400 covers the head 10 through the hall sensor 300 provided at the top of the display 180.

When the head 10 detects a magnetic field through the hall sensor 300, it may detect that it is covered by the folio cover 400. The head 10 may include a magnet 310 disposed adjacent to the hall sensor 300. When the head 10 detects that it is covered by the folio cover 400, it detects the magnetic field generated between the magnet 410 provided on the folio cover 400 and the magnet 310 provided on the head 10. As shown in FIG. 4b, the screen of the display 180 may be turned off.

Referring to FIG. 4C, the folio cover 400 may be provided with a magnet 410 inside, and the hall sensor 300 provided inside the head 10 may detect the magnetic field generated between the magnet 310 of the head 10 and the magnet 410 of the folio cover 400.

When the folio cover 400 is attached to the head 10, the distance between the hall sensor 300 and the magnet 410 of the folio cover 400 may be 3.5 mm, but this is only an example. The distance between the hall sensor 300 and the magnet provided inside the head 10 may be 50 mm, but this is only an example.

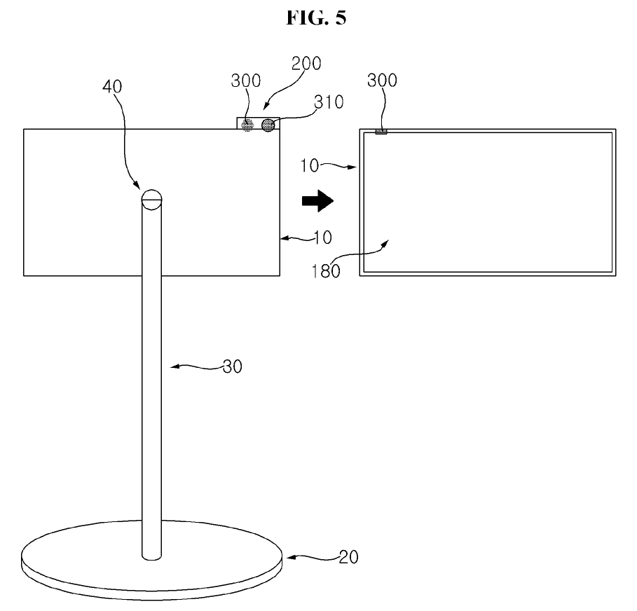

FIG. 5 is a diagram explaining that the display screen is turned off due to a remote control device when the stand and head are fastened.

Hereinafter, turning off the screen of the display 180 may mean turning off the power of the display 180, and turning on the screen of the display 180 may mean turning on the power of the display 180.

The head 10 may be provided with a magnet 310 for attachment to the folio cover 400 or the remote control device 200. The magnet 310 may be used to secure the remote control device 200 to the head 10 at the top to prevent the risk of losing the remote control device 200.

The magnet 310 provided in the head 10 may be used to fix the remote control device 200 when the stand 20, 30, 40, and 50 and the head 10 are fastened, and it may be used to couple with the folio cover 400 when the stand 20, 30, 40, 50 and the head 10 are separated.

However, conventionally, when the remote control device 200 is located on top of the magnet 310 provided on the head 10 in a state that the stand 20, 30, 40, 50 and the head 10 are fastened, the head 10 recognizes that the folio cover 400 is covered according to the detection of the magnetic field by the hall sensor 300, and turns off the screen of the display 180.

A user who wants to watch the screen in a state that the stand 20, 30, 40, 50 and the head 10 are fastened may experience discomfort in viewing as the screen is unintentionally turned off.

In an embodiment of the present disclosure, the function of the hall sensor 300 may be deactivated based on the fact that the stand 20, 30, 40, and 50 and the head 10 are coupled.

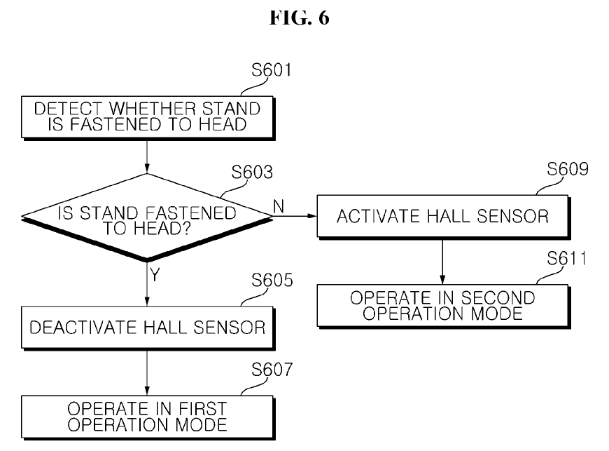

FIG. 6 is a flowchart explaining a method of operating a display device according to an embodiment of the present disclosure.

Referring to FIG. 6, the controller 170 of the display device 1 may detect whether the stand 20, 30, 40, and 50 is fastened to the head 10 (S601).

In one embodiment, the controller 170 may determine whether the stand 20, 30, 40, and 50 is fastened to the head 10 based on detection of a high signal or a low signal.

The connection of the stand 20, 30, 40, and 50 to the head 10 may mean that the rotary connector 40 is fastened to the head 10. Separation of the stand 20, 30, 40, and 50 from the head 10 may mean that the rotary connector 40 is separated from the head 10.

The controller 170 may determine whether the stand 20, 30, 40, and 50 is fastened to the head 10 by detecting a change in voltage detected at the ground detection pin.

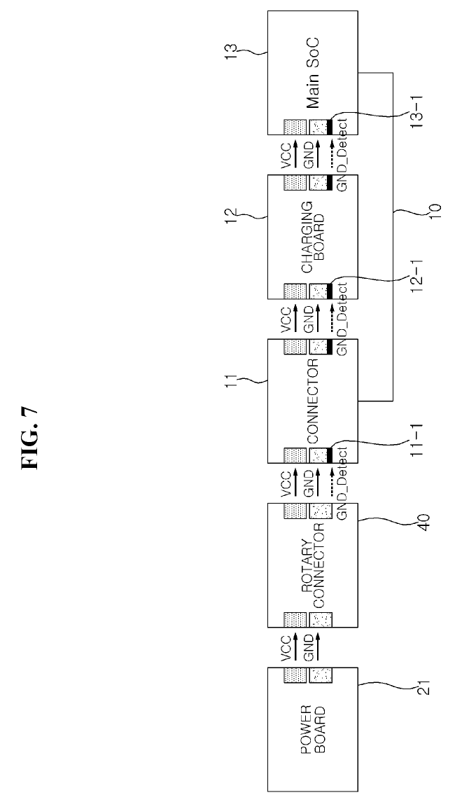

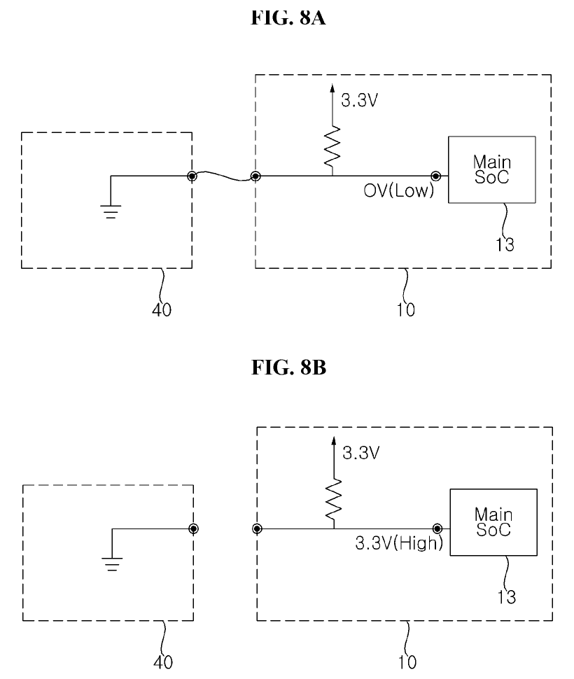

This will be explained with reference to FIGS. 7 to 8B.

FIGS. 7 to 8B are diagrams illustrating a method for detecting whether a stand is fastened to a head according to an embodiment of the present disclosure.

Referring to FIG. 7, the base 20 may be provided with a power board 21. The power board 21 may transmit power supplied from an external power source to a connector 11 of the head 10 through the rotary connector 40.

The head 10 may include the connector 11 for connection to the stand 20, 30, 40, and 50, a charging board 12 for supplying power to components provided in the head 10, and a main SoC 13. The charging board 12 and the main SoC 13 may be included in the controller 170. The controller 170 may include one or more hardware processors or one or more chips. Each of the charging board 12 and the main SoC 13 may be an example of a hardware processor or chip.

The connector 11 and the charging board 12 may be connected through a wire, and the charging board 12 and the main SoC 13 may be connected through a wire.

In one embodiment, the rotatable connector 40 and the connector 11 provided on the head 10 may be coupled through one or more pogo pins.

The power board 21 may supply power to the rotary connector 40 through a wire, and the rotary connector 40 may transmit power supplied from the power board 21 to the connector 11. The connector 11 may include a VCC terminal that receives voltage from the rotary connector 40, a ground terminal, and a ground detection pin 11-1.

When the ground terminal of the rotary connector 40 is connected to the ground detection pin 11-1 of the connector 11 of the head 10, the voltage of the ground detection pin 11-1 may be changed from the basic voltage of 3.5V to 0V. Accordingly, the voltage detected at each of the ground detection pin 12-1 of the charging board 12 and the ground detection pin 13-1 of the main SoC 13 may also be changed from 3.5V to 0V.

The main SoC 13 may determine that 3.3V corresponding to the high signal changes to 0V corresponding to the low signal as the voltage of the ground detection pin 13-1 changes from 3.5V to 0V.

The main SoC 13 may determine that the stand 20, 30, 40, and 50 is fastened to the head 10 based on detecting the low signal.

When the ground terminal of the rotary connector 40 is disconnected from the ground detection pin 11-1 of the connector 11 of the head 10, the voltage of the ground detection pin 11-1 may change from a voltage of 0V to 3.5V. Accordingly, the voltage detected at each of the ground detection pin 12-1 of the charging board 12 and the ground detection pin 13-1 of the main SoC 13 may also be changed from 0V to 3.5V.

The main SoC 13 may determine that 0V corresponding to the low signal changes to 3.3V corresponding to the high signal as the voltage of the ground detection pin 13-1 changes from 0V to 3.5V.

The main SoC 13 may determine that the stand 20, 30, 40, and 50 is separated from the head 10 based on detecting the high signal.

FIG. 8A is a diagram illustrating an equivalent circuit when the rotatable connector 40 is fastened to the head 10, and FIG. 8B is a diagram illustrating an equivalent circuit when the rotatable connector 40 is not fastened to the head 10.

When 0V is detected through the ground detection pin 13-1, the main SoC 13 may determine that the low signal has been detected. The main SoC 13 may determine that the stand 20, 30, 40, and 50 is fastened to the head 10 based on detection of the low signal.

The main SoC 13 may determine that the high signal has been detected when 3.3V is detected through the ground detection pin 13-1. The main SoC 13 may determine that the stand 20, 30, 40, and 50 is separated from the head 10 based on detection of the high signal.

Again, FIG. 6 will be described.

When it is determined that the stand 20, 30, 40, and 50 is fastened to the head 10 (S603), the controller 170 may deactivate the hall sensor 300 (S605) and operate the display device 1 in a first operation mode (S607).

The controller 170 may disable the function of the hall sensor 300 when the stand 20, 30, 40, and 50 is fastened to the head 10. The controller 170 may block power supplied to the hall sensor 300 when the stand 20, 30, 40, and 50 is fastened to the head 10. Accordingly, even if the remote control device 200 is located on top of the hall sensor 300, the hall sensor 300 does not operate and the screen of the display 180 may not turn off.

When the stand 20, 30, 40, and 50 is fastened to the head 10, the controller 170 may set the mode of the display device 1 to the first operation mode while disabling the function of the hall sensor 300.

The first operation mode may indicate that the setting values of the display device 1 are set to a first setting value set. Setting values of the display device 1 may include at least one of image quality setting values or sound equalizer setting values.

The image quality setting values may include white balance values, sharpness values, and brightness values.

When the controller 170 determines that the stand 20, 30, 40, and 50 is fastened to the head 10, an order of deactivating the hall sensor 300 and operating the first operation mode may be reversed.

As such, according to the embodiment of the present disclosure, when the stand 20, 30, 40, and 50 and the head 10 are fastened, the function of the hall sensor 300 may be deactivated. Accordingly, the problem of the screen of the display 180 turning off even when the user places the remote control device 200 adjacent to the magnet 310 inside the head 10 may be solved.

If it is determined that the stand 20, 30, 40, and 50 is not fastened to the head 10 (S603), the controller 170 may activate the hall sensor 300 (S609) and operate the display device 1 in a second operation mode (S611).

The controller 170 may activate the function of the hall sensor 300 when the stand 20, 30, 40, and 50 is separated from the head 10. The controller 170 may supply power to the hall sensor 300 when the stand 20, 30, 40, and 50 is not fastened to the head 10. Accordingly, when the folio cover 400 is located on top of the hall sensor 300, the hall sensor 300 operates and the screen of the display 180 may be turned off.

When the stand 20, 30, 40, and 50 is separated from the head 10, the controller 170 may activate the function of the hall sensor 300 and set the mode of the display device 1 to the second operation mode.

The second operation mode is a different mode from the first operation mode and may indicate that the setting values of the display device 1 are set to a second set of setting values. The setting values of the display device 1 may include at least one of an image quality setting value or a sound equalizer setting value.

When the controller 170 determines that the stand 20, 30, 40, and 50 is separated from the head 10, an order of activating the hall sensor 300 and operating the second operation mode may be reversed.

In this way, according to the embodiment of the present disclosure, the setting values of the display device 1 may be automatically optimized depending on whether the stand 20, 30, 40, or 50 is fastened to the head 10. Accordingly, the user does not need separate manual operation, and the ease of use of the display device 1 may be greatly improved.

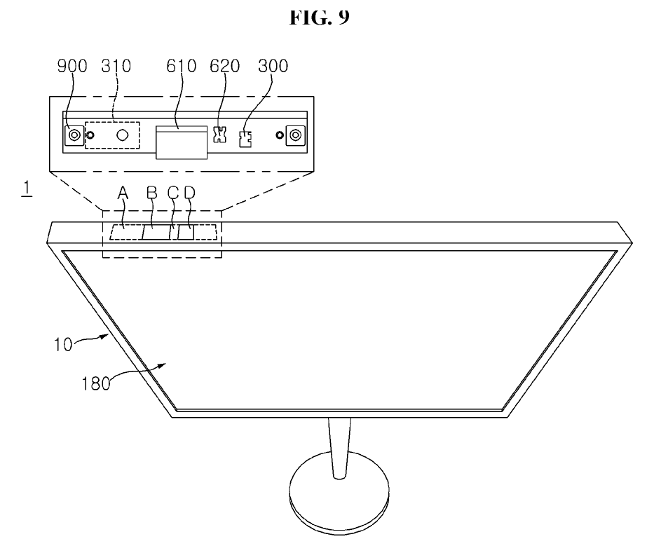

FIG. 9 is a diagram explaining the arrangement structure of a magnet and a hall sensor provided in a head according to an embodiment of the present disclosure.

Referring to FIG. 9, a component array 900 provided inside an upper part of the head 10 is shown.

The component array 900 may include the magnet 310, an IR receiver 610 for receiving an IR signal from the remote control device 200, a microphone 620 for receiving a voice, and the hall sensor 300.

The magnet 310 may be placed at the first position A, the IR receiver 610 may be placed at the second position B to the right of the first position A, the microphone 620 may be placed at the third position C to the right of the second position B, and the hall sensor 300 may be placed at the fourth position D to the right of the third position C.

The display device 1 according to an embodiment of the present disclosure may comprise a head including a display 180, a sensor used to turn on or off a screen of the display, and a controller 170, wherein the controller 170 may detect whether a stand 20, 30, 40, 50 supporting the head and the head are fastened, and deactivate a function of the sensor when it is detected that the stand is fastened with the head.

The controller 170 may activate the function of the sensor when it is detected that the stand is separated from the head.

The controller 170 may operate a mode of the display device in a first operation mode when it is detected that the stand is fastened to the head, and operate the mode of the display device in a second operation mode when it is detected that the stand is separated from the head.

The first operation mode may be a mode in which setting values of the display device are set to a first setting value set, the second operation mode may be a mode in which the setting values of the display device are set to a second setting value set, and the setting values may include one or more of picture quality settings or sound settings.

The sensor is a hall sensor 300 that detects a magnetic field, the controller 170 may turn off the screen of the display based on a magnetic field generated between a magnet 310 provided in the head 10 and a magnet 410 provided in a folio cover 400 that covers the head 10.

The hall sensor 300 and the magnet 310 provided in the head 10 may be disposed at the top of the display 180, and the hall sensor 300 and the magnet 310 provided in the head may be disposed at a predetermined distance from each other.

The controller 170 may detect whether the stand and the head are fastened based on a voltage detected through a ground detection pin.

According to an embodiment of the present invention, the above-described method may be implemented as processor-readable code on a program-recorded medium. Examples of media that the processor may read include ROM, RAM, CD-ROM, magnetic tape, floppy disk, and optical data storage devices.

The display device described above is not limited to the configuration and method of the above-described embodiments, and may be configured by selectively combining all or part of each embodiment so that various modifications may be made.

What is claimed is:

1. A display device, comprising:
a head including a display, a sensor used to turn on or off a screen of the display, and a controller,
wherein the controller is configured to:
detect whether a stand supporting the head and the head are fastened, and
deactivate a function of the sensor when it is detected that the stand is fastened with the head.

2. The display device of claim 1, wherein the controller is further configured to:
activate the function of the sensor when it is detected that the stand is separated from the head.

3. The display device of claim 1, wherein the controller is further configured to:
operate a mode of the display device in a first operation mode when it is detected that the stand is fastened to the head, and
operate the mode of the display device in a second operation mode when it is detected that the stand is separated from the head.

4. The display device of claim 3, wherein the first operation mode is a mode in which setting values of the display device are set to a first setting value set, the second operation mode is a mode in which the setting values of the display device are set to a second setting value set, and the setting values includes one or more of picture quality settings or sound settings.

5. The display device of claim 1, wherein the sensor is a hall sensor that detects a magnetic field,
wherein the controller is further configured to:
turn off the screen of the display based on a magnetic field generated between a magnet provided in the head and a magnet provided in a folio cover that covers the head.

6. The display device of claim 5, wherein the hall sensor and the magnet provided in the head are disposed at the top of the display, and the hall sensor and the magnet provided in the head are disposed at a predetermined distance from each other.

7. The display device of claim 1, wherein the controller is further configured to:
detect whether the stand and the head are fastened based on a voltage detected through a ground detection pin.

8. The display device of claim 1, further comprising:
the stand.

9. A method of operating a display device, wherein the display device comprises a head including a display, a sensor used to turn on or off a screen of the display, and a controller,
the method comprising:
detecting whether a stand supporting the head and the head are fastened; and
deactivating a function of the sensor when it is detected that the stand is fastened with the head.

10. The method of claim 9, further comprising:
activating the function of the sensor when it is detected that the stand is separated from the head.

11. The method of claim 9, further comprising:
operating a mode of the display device in a first operation mode when it is detected that the stand is fastened to the head, and
operating the mode of the display device in a second operation mode when it is detected that the stand is separated from the head.

12. The method of claim 11, wherein the first operation mode is a mode in which setting values of the display device are set to a first setting value set, the second operation mode is a mode in which the setting values of the display device are set to a second setting value set, and the setting values includes one or more of picture quality settings or sound settings.

13. The method of claim 9, wherein the sensor is a hall sensor that detects a magnetic field,
wherein the method further comprising:
turning off the screen of the display based on a magnetic field generated between a magnet provided in the head and a magnet provided in a folio cover that covers the head.

14. The method of claim 13, wherein the hall sensor and the magnet provided in the head are disposed at the top of the display, and the hall sensor and the magnet provided in the head are disposed at a predetermined distance from each other.

15. The method of claim 9, further comprising:
detecting whether the stand and the head are fastened based on a voltage detected through a ground detection pin.
